(19) United States
(12) Patent Application Publication
(10) Pub. No.: US 2026/0122749 A1
(43) Pub. Date: Apr. 30, 2026

(54) EUV LIGHT GENERATION APPARATUS AND ELECTRONIC DEVICE MANUFACTURING METHOD

(71) Applicant: Gigaphoton Inc., Tochigi (JP)

(72) Inventors: Yuichi NISHIMURA, Oyama-shi (JP); Yoshifumi UENO, Oyama-shi (JP)

(73) Assignee: Gigaphoton Inc., Tochigi (JP)

(21) Appl. No.: 19/316,228

(22) Filed: Sep. 2, 2025

(30) Foreign Application Priority Data
Oct. 30, 2024 (JP) 2024-191129

(51) Int. Cl. H05G 2/00; G01N 21/956; G03F 1/22; G03F 7/00

(52) U.S. Cl. CPC H05G 2/0086; G01N 21/956; G03F 1/22; G03F 7/70033; G03F 7/7055; G03F 7/7085; H05G 2/0027; G01N 2021/95676; G01N 2201/061

(57) ABSTRACT

An EUV light generation apparatus is configured to generate EUV light by irradiating a target output into a chamber with laser light. Here, the EUV light generation apparatus includes a light concentrating unit configured to concentrate the laser light on the target, an angle adjustment mirror configured to adjust an incident angle of the laser light on the light concentrating unit, a position adjustment mirror configured to adjust an incident position of the laser light on the light concentrating unit, a beam monitor configured to measure a parameter related to variation in the incident position, and a processor configured to perform control of adjustment by the position adjustment mirror based on a measurement value of the parameter when performing adjustment by the angle adjustment mirror.

### CROSS-REFERENCE TO RELATED APPLICATIONS

The present application claims the benefit of Japanese Patent Application No. 2024/191129, filed on Oct. 30, 2024, the entire contents of which are hereby incorporated by reference.

### BACKGROUND

### 1. Technical Field

The present disclosure relates to an EUV light generation apparatus and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: US Patent Application Publication No. 2023/0101779
Patent Document 2: U.S. Pat. No. 8,395,133
Patent Document 3: U.S. Pat. No. 10,102,938

### SUMMARY

An EUV light generation apparatus according to an aspect of the present disclosure is configured to generate EUV light by irradiating a target output into a chamber with laser light. Here, the EUV light generation apparatus includes a light concentrating unit configured to concentrate the laser light on the target, an angle adjustment mirror configured to adjust an incident angle of the laser light on the light concentrating unit, a position adjustment mirror configured to adjust an incident position of the laser light on the light concentrating unit, a beam monitor configured to measure a parameter related to variation in the incident position, and a processor configured to perform control of adjustment by the position adjustment mirror based on a measurement value of the parameter when performing adjustment by the angle adjustment mirror.

An electronic device manufacturing method according to an aspect of the present disclosure includes outputting EUV light generated by an EUV light generation apparatus to an exposure apparatus, and exposing a photosensitive substrate to the EUV light in the exposure apparatus to manufacture an electronic device. Here, the EUV light generation apparatus is configured to generate the EUV light by irradiating a target output into a chamber with laser light, and includes a light concentrating unit configured to concentrate the laser light on the target, an angle adjustment mirror configured to adjust an incident angle of the laser light on the light concentrating unit, a position adjustment mirror configured to adjust an incident position of the laser light on the light concentrating unit, a beam monitor configured to measure a parameter related to variation in the incident position, and a processor configured to perform control of adjustment by the position adjustment mirror based on a measurement value of the parameter when performing adjustment by the angle adjustment mirror.

An electronic device manufacturing method according to an aspect of the present disclosure includes inspecting a defect of a mask by irradiating the mask with EUV light generated by an EUV light generation apparatus, selecting a mask using a result of the inspection, and exposing and transferring a pattern formed on the selected mask onto a photosensitive substrate. Here, the EUV light generation apparatus is configured to generate the EUV light by irradiating a target output into a chamber with laser light, and includes a light concentrating unit configured to concentrate the laser light on the target, an angle adjustment mirror configured to adjust an incident angle of the laser light on the light concentrating unit, a position adjustment mirror configured to adjust an incident position of the laser light on the light concentrating unit, a beam monitor configured to measure a parameter related to variation in the incident position, and a processor configured to perform control of adjustment by the position adjustment mirror based on a measurement value of the parameter when performing adjustment by the angle adjustment mirror.

### BRIEF DESCRIPTION OF THE DRAWINGS

Embodiments of the present disclosure will be described below merely as examples with reference to the accompanying drawings.

FIG. 1 is a view schematically showing an LPP EUV light generation system.

FIG. 2 is a view showing the configuration of the EUV light generation system according to a comparative example.

FIG. 3 is a diagram showing the arrangement of a plurality of EUV energy sensors.

FIG. 4 is a flowchart showing a processing procedure of irradiation position control.

FIG. 5 is a flowchart showing an adjustment algorithm used in MPL irradiation position adjustment and PPL irradiation position adjustment.

FIG. 6 is a flowchart showing position adjustment according to step S100 of FIG. 5.

FIG. 7 is a diagram showing an example of acquiring values of an index.

FIG. 8 is a diagram showing an example of acquiring values of the index.

FIG. 9 is a diagram showing an example of a process for irradiation position change in a case in which a gradient is equal to or less than a threshold.

FIG. 10 is a diagram showing an example of a process for additional search and changing the irradiation position in a case in which the gradient is more than the threshold.

FIG. 11 is a diagram conceptually showing the relationship between an incident position of MPL light on a light concentrating unit and a CE.

FIG. 12 is a diagram conceptually showing variation in the incident position by adjusting an incident angle of the MPL light.

FIG. 13 is a view showing the configuration of the EUV light generation system according to a first embodiment.

FIG. 14 is a diagram showing the configuration of a beam monitor.

FIG. 15 is a diagram showing the configuration of the beam monitor.

FIG. 16 is a diagram showing the configuration of the beam monitor according to a first modification.

FIG. 17 is a diagram showing the configuration of the beam monitor according to the first modification.

FIG. 18 is a view showing the configuration of the EUV light generation system according to a second embodiment.

FIG. 19 is a diagram schematically showing the configuration of an exposure apparatus connected to the EUV light generation system.

FIG. 20 is a diagram schematically showing the configuration of an inspection apparatus connected to the EUV light generation system.

### DESCRIPTION OF EMBODIMENTS

### <Contents>

1. Overall description of EUV light generation system
1.1 Configuration
1.2 Operation
   2. Comparative example
2.1 Configuration
2.2 Operation
2.3 Problem

### 3. First Embodiment

3.1 Configuration
3.2 Operation
3.3 Effect
3.4 Modification
   3.4.1 First modification
   3.4.2 Other modification

### 4. Second Embodiment

4.1 Configuration
4.2 Operation
4.3 Effect
   5. Electronic device manufacturing method

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overall Description of EUV Light Generation System

### 1.1 Configuration

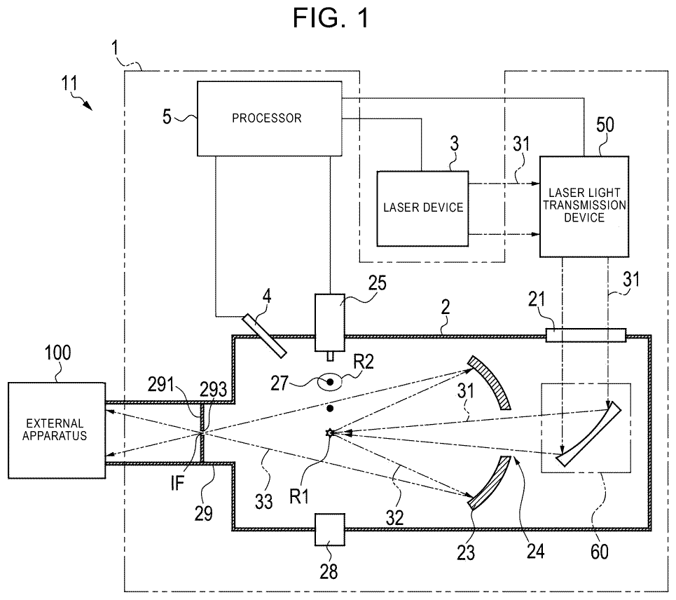

FIG. 1 schematically shows the configuration of an LPP EUV light generation system 11. An EUV light generation apparatus 1 is used together with a laser device 3. In the present disclosure, a system including the EUV light generation apparatus 1 and the laser device 3 is referred to as the EUV light generation system 11. The EUV light generation apparatus 1 includes a chamber 2 and a target supply device 25. The chamber 2 is a sealable container. The target supply device 25 supplies a target 27 in a droplet form into the chamber 2. The material of the target 27 may include tin, terbium, gadolinium, lithium, xenon, or a combination of any two or more thereof.

A through hole is formed in a wall of the chamber 2. The through hole is blocked by a window 21 through which pulse laser light 31 output from the laser device 3 passes. An EUV light concentrating mirror 23 having a spheroidal reflection surface is arranged in the chamber 2. The EUV light concentrating mirror 23 has first and second focal points. A multilayer reflection film in which molybdenum and silicon are alternately stacked is formed on a surface of the EUV light concentrating mirror 23. The EUV light concentrating mirror 23 is arranged such that the first focal point is located in a plasma generation region R1 and the second focal point is located at an intermediate focal point IF. A through hole 24 is formed at the center of the EUV light concentrating mirror 23, and the pulse laser light 31 passes through the through hole 24. The EUV light concentrating mirror 23 is rotationally symmetrical with respect to the optical axis of the pulse laser light 31. The pulse laser light 31 is an example of the “laser light” according to the technology of the present disclosure.

The EUV light generation apparatus 1 includes a target sensor 4, a processor 5, and the like. The target sensor 4 detects at least one of the presence, trajectory, position, size, and velocity of the target 27. The target sensor 4 may have an imaging function.

The target sensor 4 is a sensor for detecting the target 27 passing through a target detection region R2. The target detection region R2 is a predetermined region in the chamber 2, and is a region located at a predetermined position on the target trajectory between the target supply device 25 and the plasma generation region R1.

Further, the target sensor 4 includes a mist sensor for acquiring mist information that is information of the target 27 diffused into a mist form by being irradiated with PPL light 31P described later. For example, the mist sensor is an imaging device that images the target 27 irradiated with illumination light or a shadow of the target 27, and outputs image data. The processor 5 acquires the mist information based on the image data output from the mist sensor. For example, the mist information includes the size, position, angle, and the like of the mist-like target 27.

Further, the EUV light generation apparatus 1 includes a connection portion 29 providing communication between the inside of the chamber 2 and the inside of an external apparatus 100. A wall 291 in which an aperture 293 is formed is arranged in the connection portion 29. The wall 291 is arranged such that the aperture 293 is located at the second focal point of the EUV light concentrating mirror 23. For example, the external apparatus 100 is an exposure apparatus 100a.

Further, the EUV light generation apparatus 1 includes a laser light transmission device 50, a light concentrating unit 60, and a target collection unit 28 for collecting the target 27. The laser light transmission device 50 includes an optical element for defining a transmission state of the laser light, and an actuator for adjusting the position, angle, and the like of the optical element.

Further, a buffer gas is supplied into the chamber 2 from a buffer gas supply device (not shown) to protect the EUV light concentrating mirror 23 from debris generated during plasma generation. In the chamber 2, the buffer gas supplied from a supply port of the buffer gas supply device flows toward a dust removing device (not shown), and a flow field is formed. The buffer gas is hydrogen, nitrogen, or a noble gas such as helium and argon.

### 1.2 Operation

Referring to FIG. 1, operation of an exemplary LPP EUV light generation system 11 will be described. The pulse laser light 31 output from the laser device 3 enters, via the laser light transmission device 50, the chamber 2 through the window 21. The pulse laser light 31 having entered the chamber 2 travels in the chamber 2 along a laser light path, is concentrated by the light concentrating unit 60, and is radiated to the target 27.

The target supply device 25 outputs the target 27 toward the plasma generation region R1 in the chamber 2. The target 27 is irradiated with the pulse laser light 31. The target 27 irradiated with the pulse laser light 31 is turned into plasma, and radiation light 32 is radiated from the plasma. EUV light 33 contained in the radiation light 32 is selectively reflected by the EUV light concentrating mirror 23. The EUV light 33 reflected by the EUV light concentrating mirror 23 is concentrated on the intermediate focal point IF and output to the external apparatus 100. Here, one target 27 may be irradiated with a plurality of pulses included in the pulse laser light 31.

The processor 5 controls the entire EUV light generation system 11. Based on the detection result of the target sensor 4, the processor 5 controls timing at which the target 27 is output, an output direction of the target 27, and the like. Further, the processor 5 controls oscillation timing of the laser device 3, a travel direction of the pulse laser light 31, the concentration position, and the like. The above-described various kinds of control are merely examples, and other control may be added as necessary.

### 2. Comparative Example

### 2.1 Configuration

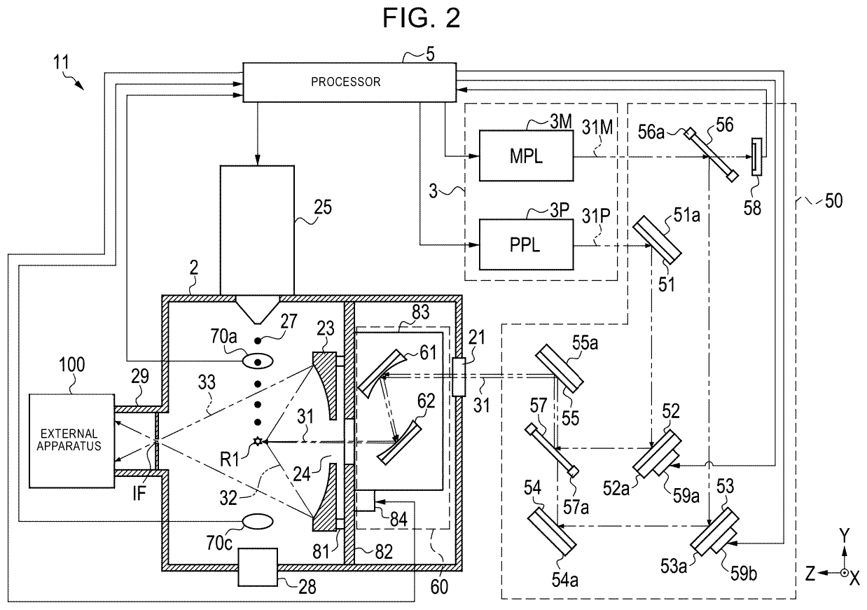

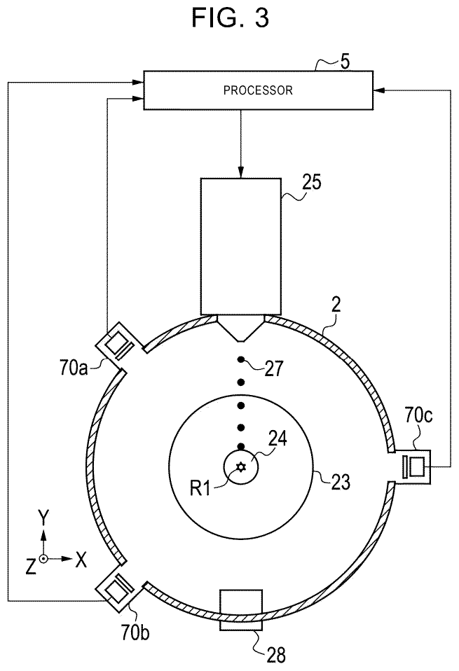

FIG. 2 schematically shows the configuration of the EUV light generation system 11 according to a comparative example. FIG. 3 shows the arrangement of EUV energy sensors 70a to 70c. As shown in FIGS. 2 and 3, the travel direction of the pulse laser light 31 output from the light concentrating unit 60 is represented by a Z-axis direction. The direction opposite to the output direction of the target 27 is represented by a Y-axis direction. A direction perpendicular to both the Z-axis direction and the Y-axis direction is represented by an X-axis direction. FIG. 2 shows a YZ cross section of the chamber 2. FIG. 3 shows an XY cross section of the chamber 2.

The light concentrating unit 60, the EUV light concentrating mirror 23, the target collection unit 28, the EUV energy sensors 70a to 70c, an EUV light concentrating mirror holder 81, plates 82, 83, and a stage 84 are provided in the chamber 2. The target supply device 25 is attached to the chamber 2.

The target supply device 25 is arranged to penetrate a through hole formed in a wall of the chamber 2. The target supply device 25 stores the molten material of the target 27 therein. The target supply device 25 has an opening located in the chamber 2. A vibration device (not shown) is arranged in the vicinity of the opening of the target supply device 25.

The target supply device 25 includes an XZ stage (not shown). The processor 5 controls the XZ stage based on the output of the target sensor 4 (see FIG. 1). The trajectory of the target 27 can be adjusted so that the target 27 passes through the plasma generation region R1 by controlling the XZ stage.

The laser device 3 includes a prepulse laser (PPL) 3P and a main pulse laser (MPL) 3M. The PPL 3P is configured to output the PPL light 31P. The MPL 3M is configured to output MPL light 31M. The PPL 3P is configured by, for example, a YAG laser device or a laser device using Nd: YVO₄. The MPL 3M is configured by, for example, a CO₂ laser device. The MPL 3M may be configured by a YAG laser device or a laser device using Nd: YVO₄.

The laser light transmission device 50 includes high reflection mirrors 51 to 55, a beam splitter 56, a combiner 57, a laser energy sensor 58, and actuators 59a, 59b. The high reflection mirrors 51 to 55, the beam splitter 56, and the combiner 57 are held by holders 51a to 57a, respectively.

The high reflection mirror 51 is arranged on the optical path of the PPL light 31P output from the PPL 3P. The high reflection mirror 52 is arranged on the optical path of the PPL light 31P reflected by the high reflection mirror 51.

The beam splitter 56 is arranged on the optical path of the MPL light 31M output from the MPL 3M. The beam splitter 56 is configured to reflect the MPL light 31M at a high reflectance. Further, the beam splitter 56 is configured to transmit a part of the MPL light 31M toward the laser energy sensor 58.

The high reflection mirror 53 is arranged on the optical path of the MPL light 31M reflected by the beam splitter 56. The high reflection mirror 54 is arranged on the optical path of the MPL light 31M reflected by the high reflection mirror 53.

The combiner 57 is arranged at a position where the optical path of the PPL light 31P reflected by the high reflection mirror 52 intersects with the optical path of the MPL light 31M reflected by the high reflection mirror 54. The combiner 57 is configured to reflect the PPL light 31P at a high reflectance and transmit the MPL light 31M at a high transmittance. The combiner 57 is configured to substantially match the optical path axes of the PPL light 31P and the MPL light 31M.

The high reflection mirror 55 is arranged on the optical path of the PPL light 31P reflected by the combiner 57 and the optical path of the MPL light 31M transmitted through the combiner 57. The high reflection mirror 55 is configured to reflect the PPL light 31P and the MPL light 31M toward the inside of the chamber 2. In the present disclosure, for convenience of explanation, the PPL light 31P and the MPL light 31M reflected by the high reflection mirror 55 may be collectively referred to as the pulse laser light 31.

The actuator 59a is attached to the holder 52a. The actuator 59a is connected to the processor 5, and is configured to be capable of adjusting the angle at which the PPL light 31P enters the light concentrating unit 60 by changing the angle of the high reflection mirror 52. The actuator 59a is not limited to the above arrangement. The actuator 59a may be arranged to be capable of changing the angle of any of the mirrors arranged on the optical path of the PPL light 31P.

The actuator 59b is attached to the holder 53a. The actuator 59b is connected to the processor 5, and is configured to be capable of adjusting the angle at which the MPL light 31M enters the light concentrating unit 60 by changing the angle of the high reflection mirror 53. The actuator 59b is not limited to the above arrangement. The actuator 59b may be arranged to be capable of changing the angle of any of the mirrors arranged on the optical path of the MPL light 31M.

Hereinafter, changing the angle of the mirror may be simply referred to as “adjusting the mirror”. Further, the mirror to be adjusted may be a combiner.

The laser energy sensor 58 is arranged on the optical path of the MPL light 31M transmitted through the beam splitter 56. The laser energy sensor 58 measures the energy of the MPL light 31M transmitted through the beam splitter 56 and outputs the measurement value to the processor 5. The laser energy sensor 58 is not limited to the above arrangement. The laser energy sensor 58 may be arranged such that any of the high reflection mirrors arranged on the optical path of the MPL light 31M is changed to a beam splitter to measure light transmitted therethrough.

The plate 82 is fixed to the chamber 2. The plate 82 supports the plate 83. The light concentrating unit 60 includes laser light concentrating mirrors 61, 62.

The stage 84 is capable of adjusting the position of the plate 83 with respect to the plate 82. By adjusting the position of the plate 83, the position of the light concentrating unit 60 is adjusted. The position of the light concentrating unit 60 is adjusted so that the pulse laser light 31 reflected by the laser light concentrating mirrors 61, 62 is concentrated at the plasma generation region R1.

The EUV light concentrating mirror 23 is fixed to the plate 82 via the EUV light concentrating mirror holder 81.

As shown in FIG. 3, the EUV energy sensors 70a to 70c are attached to the wall surface of the chamber 2. Each of the EUV energy sensors 70a to 70c is directed toward the plasma generation region R1. The EUV energy sensors 70a, 70b are arranged at positions to be a mirror image with respect to each other across a virtual plane being parallel to the XZ plane and passing through the plasma generation region R1. The EUV energy sensor 70c is arranged on the opposite side of the EUV energy sensors 70a, 70b across a virtual plane being parallel to the YZ plane and passing through the plasma generation region R1 and on a virtual line being parallel to the Z axis and passing through the plasma generation region R1. Each of the EUV energy sensors 70a to 70c measures the energy of the EUV light 33 included in the radiation light 32 emitted from the target 27 in the plasma generation region R1, and outputs the measurement value to the processor 5. Hereinafter, the energy of the EUV light 33 is referred to as the EUV energy.

### 2.2 Operation

The processor 5 outputs a control signal to the target supply device 25. The target substance stored in the target supply device 25 is maintained at a temperature equal to or higher than the melting point of the target substance by a heater (not shown). The target substance in the target supply device 25 is pressurized by an inert gas supplied from a gas supply device (not shown) into the target supply device 25.

The target substance pressurized by the inert gas is output as a jet through the above-described opening. The jet of the target substance is separated into a plurality of droplets by vibrating components of the target supply device 25 at least around the opening by the above-described vibration device. Each droplet constitutes the target 27. The target 27 moves in the −Y-axis direction along the trajectory from the target supply device 25 to the plasma generation region R1. The target collection unit 28 collects the target 27 having passed through the plasma generation region R1.

The target 27 output into the chamber 2 passes through the target detection region R2. The target 27 having passed through the target detection region R2 is supplied to the plasma generation region R1.

The target sensor 4 detects the timing at which the target 27 passes through the target detection region R2. The processor 5 receives a passage timing signal transmitted from the target sensor 4. The processor 5 determines the timing at which the passage timing signal becomes lower than a predetermined threshold as the timing at which the target 27 passes through the target detection region R2. The processor 5 generates a target detection signal indicating that the target 27 has passed through the target detection region R2 at the timing at which the passage timing signal becomes lower than the predetermined threshold.

The processor 5 outputs a first trigger signal to the PPL 3P at a timing delayed by a predetermined delay time from the timing at which the target detection signal is generated, the first trigger signal giving a trigger to output the PPL light 31P. The PPL 3P outputs the PPL light 31P in accordance with the first trigger signal. The processor 5 outputs a second trigger signal to the MPL 3M after outputting the first trigger signal. The MPL 3M outputs the MPL light 31M in accordance with the second trigger signal. Thus, the laser device 3 outputs the PPL light 31P and the MPL light 31M in this order. The PPL light 31P preferably has a pulse time width on the order of picoseconds. The order of picoseconds means being equal to or more than 1 ps and equal to or less than 1 ns. Here, the pulse time width of the PPL light 31P may be equal to or more than 1 ns and less than 1 μs.

The PPL light 31P and the MPL light 31M enter the laser light transmission device 50. The PPL light 31P and the MPL light 31M are guided to the light concentrating unit 60 as the pulse laser light 31 via the laser light transmission device 50. The pulse laser light 31 is reflected by the laser light concentrating mirror 61. The pulse laser light 31 reflected by the laser light concentrating mirror 61 is reflected by the laser light concentrating mirror 62 and is concentrated at the plasma generation region R1.

The stage 84 changes the position of the plate 83 with respect to the plate 82 by a control signal output from the processor 5. By changing the position of the plate 83, the light concentrating unit 60 is moved. As the light concentrating unit 60 is moved, the irradiation positions of the PPL light 31P and the MPL light 31M are moved.

The actuator 59a adjusts the incident angle of the PPL light 31P on the light concentrating unit 60 by adjusting the high reflection mirror 52 based on the control signal output from the processor 5. Thus, the position of the PPL light 31P in the plasma generation region R1 is adjusted.

Further, the actuator 59b adjusts the incident angle of the MPL light 31M on the light concentrating unit 60 by adjusting the high reflection mirror 53 based on the control signal output from the processor 5. Thus, the position of the MPL light 31M in the plasma generation region R1 is adjusted.

At the timing at which one target 27 reaches the plasma generation region R1, the target 27 is irradiated with the PPL light 31P. The target 27 irradiated with the PPL light 31P is diffused into a mist form. At the timing at which the target 27 is diffused into a desired size, the mist-like target 27 is irradiated with the MPL light 31M.

The target 27 irradiated with the MPL light 31M is turned into plasma and emits the radiation light 32. The EUV light 33 included in the radiation light 32 is selectively reflected by the EUV light concentrating mirror 23 and is concentrated on the intermediate focal point IF at the connection portion 29. The EUV light 33 concentrated on the intermediate focal point IF is output toward the external apparatus 100.

When the irradiation position of the pulse laser light 31 at the plasma generation region R1 deviates from the center of the droplet form target 27, a problem such as a decrease in the EUV energy occurs. However, it may be difficult to directly measure the deviation between the irradiation position of the pulse laser light 31 and the center of the target 27. Therefore, the processor 120 controls the pulse energy of the MPL light 31M such that the EUV energy becomes constant during continuous operation of the EUV light generation system 11. For example, the processor 5 controls the pulse energy of the MPL light 31M such that the sum or average of the output values of the EUV energy sensors 70a to 70c falls within a predetermined range. Hereinafter, the pulse energy of the MPL light 31M at the plasma generation region R1 is referred to as the MPL energy.

However, it is difficult to maintain the EUV energy constant only by controlling the MPL energy. This is because the thermal deformation of the optical elements on the optical path changes the characteristics of the EUV energy. Therefore, the processor 5 performs irradiation position control of the MPL light 31M using a conversion efficiency (CE) indicating the efficiency of converting the MPL energy into the EUV energy as an index. Here, the CE is a value obtained by dividing the sum or average of the output values of the EUV energy sensors 70a to 70c by the measurement value of the MPL energy measured by the laser energy sensor 58.

Further, when a positional deviation occurs in the irradiation position of the PPL light 31P with respect to the target 27, the EUV energy may decrease due to insufficient size of the target 27 diffused in a mist form and the like. Therefore, the processor 5 controls the irradiation position of the PPL light 31P using mist information of the target 27 as an index. In the comparative example, the processor 5 controls the irradiation position of the PPL light 31P based on the size of the mist-like target 27 measured using the image data output from the mist sensor. Hereinafter, the size of the mist-like target 27 is referred to as the “mist size”.

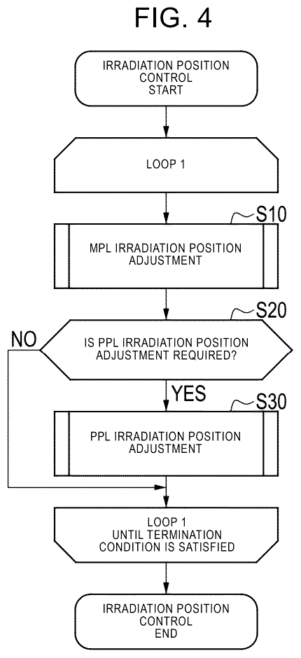

FIG. 4 shows a processing procedure of the irradiation position control. In the irradiation position control, the processor 5 executes loop 1 including a process (step S10) of performing MPL irradiation position adjustment for adjusting the position of the irradiation position of the MPL light 31M and a process (step S30) of PPL irradiation position adjustment for adjusting the irradiation position of the PPL light 31P. Further, the irradiation position control includes a process (step S20) of determining whether or not to perform the PPL irradiation position adjustment.

In loop 1, the processor determines whether or not the PPL irradiation position adjustment based on the mist information described above is necessary (step S20). When it is determined to be necessary (step S20: YES), the processor 5 executes the PPL irradiation position adjustment. For example, the processor 5 performs the PPL irradiation position adjustment when the mist size is smaller than a certain value.

When a predetermined termination condition is satisfied, the processor 5 exits loop 1 and terminates the irradiation position control. The termination condition of loop 1 is detection of transition to a state involving stop of EUV light generation such as receiving an EUV light output stop command from the external apparatus 100, for example.

In step S10, the processor 5 performs the MPL irradiation position adjustment by controlling the actuator 59b using the CE as an index. Further, in step S30, the processor 5 performs the PPL irradiation position adjustment by controlling the actuator 59a using the mist size as an index.

The processor 5 can execute the MPL irradiation position adjustment and the PPL irradiation position adjustment using a common adjustment algorithm. Here, the index, a search width A, and an allowable value of positional deviation dX, which will be described later, are different between the MPL irradiation position adjustment and the PPL irradiation position adjustment.

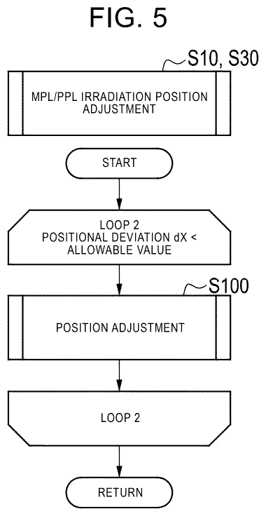

FIG. 5 shows the adjustment algorithm used in the MPL irradiation position adjustment and the PPL irradiation position adjustment. According to the adjustment algorithm, the processor 5 executes loop 2 including a process (step S100) of repeatedly performing the position adjustment. In loop 2, the processor 5 changes an adjustment target axis each time the position adjustment is performed. The processor 5 repeats the position adjustment in the X-axis direction and the position adjustment in the Y-axis direction in the order of the X axis, the Y axis, the X axis, . . . , or in the order of the Y axis, the X axis, the Y axis

When a predetermined termination condition is satisfied, the processor 5 exits loop 2 and terminates the position adjustment. The termination condition of loop 2 is, for example, that the positional deviation dX becomes less than an allowable value. The positional deviation dX is, for example, with the position adjustment in the X-axis direction performed twice consecutively, an absolute value of the difference between a position adjusted by the first position adjustment in the X-axis direction and a position adjusted by the second position adjustment in the X-axis direction. When the positional deviation dX is equal to or more than the allowable value, the processor 5 continues the position adjustment with the second adjustment position in the X-axis direction set as the first adjustment position. Here, the allowable value is an upper limit value of the positional deviation dX at which no significant improvement can be expected even if the position adjustment is further performed.

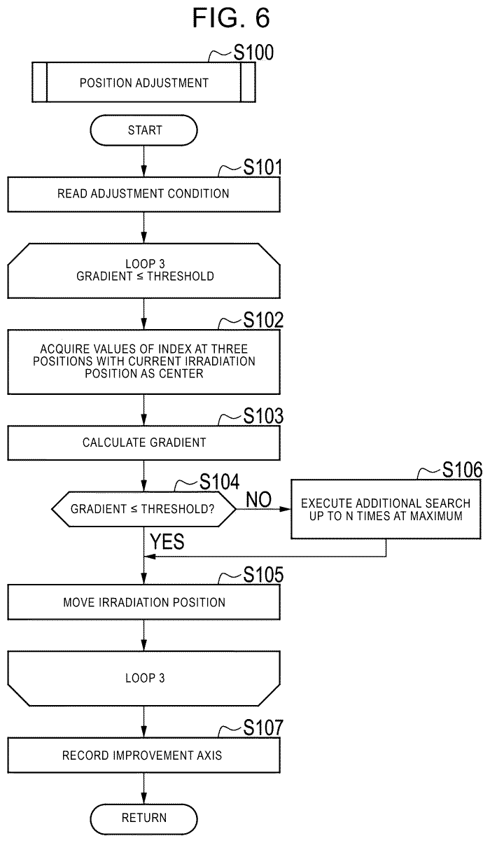

FIG. 6 shows details of the position adjustment according to step S100 of FIG. 5. First, the processor 5 reads an adjustment condition from the memory (step S101). For example, the adjustment condition includes a current irradiation position, an adjustment target axis, a threshold, the search width A, a minute amount d, and a number of additional searches N. The search width A is about 0.5 to 5 μm. For example, the search width A is determined by the sensitivity of the CE or the mist size to the irradiation position. Further, the search width A may have different values in the X-axis direction and the Y-axis direction. In particular, when the spot intensity distribution of the pulse laser light 31 is elliptic, it is preferable to set different values in the X-axis direction and the Y-axis direction.

Next, the processor 5 executes loop 3 in which the termination condition is that the gradient of an index becomes equal to or less than the threshold. In loop 3, the processor 5 first acquires values of the index at three positions with the current irradiation position as the center. (step S102). Specifically, the processor 5 changes the irradiation position in the direction of the adjustment target axis by ±Δ from the current irradiation position, and acquires values of the index at the three positions. The irradiation position moved in the position adjustment according to step S100 is also referred to as a search position. When the irradiation position of the MPL light 31M is to be changed, the index is CE. When the irradiation position of the PPL light 31P is to be changed, the index is the mist size.

Next, the processor 5 calculates the gradient of the index with respect to the search position based on the acquired values of the index at the three positions (step S103). For example, the gradient is an absolute value of the gradient of an approximate straight line calculated based on the values of the index at the three positions.

Next, the processor 5 determines whether or not the calculated gradient is equal to or less than the threshold (step S104). When the gradient is equal to or less than the threshold (step S104: YES), the processor 5 advances processing to step S105.

On the other hand, when the gradient is more than the threshold (step S104: NO), the processor 5 executes additional searches up to N times at maximum (step S106), and advances processing to step S105. The additional search is a process of acquiring values of the index while changing the search position by the search width A in the direction in which the index improves, and searching an improved position. Specifically, the processor 5 evaluates the values of the index while changing the search position in the improvement direction, and sets the search position immediately before the value of the index deteriorates as the improvement position. Here, in a case in which values of the index continue to be improved without deteriorating even when the search position is changed N times, the N-th change position is set as the improvement position. Here, in both cases in which the index is the CE and in which the index is the mist size, the direction in which values of the index increase is the improvement direction.

In step S105, the processor 5 moves the irradiation position. Specifically, when the gradient is equal to or less than the threshold, the processor 5 moves the irradiation position by a minute amount d in the improvement direction. The minute amount d is a value equal to or less than the search width A. When the gradient is more than the threshold and the additional search is performed, the processor 5 moves the irradiation position to the improvement position.

The processor 5 repeatedly executes steps S102 to S106 until the gradient becomes equal to or less than the threshold, and when the gradient becomes equal to or less than the threshold, terminates loop 3, records the improvement axis in the memory (step S107), and terminates the process. The improvement axis is a coordinate axis on which improvement is obtained by the additional search, and is the X axis or the Y axis. The improvement axis is stored in the memory in an overwritten manner, and is read as the adjustment target axis by the processor 5 in step S101 at the time of the next position adjustment. When the processor 5 terminates loop 3 without performing the additional search, the process is terminated without executing step S107.

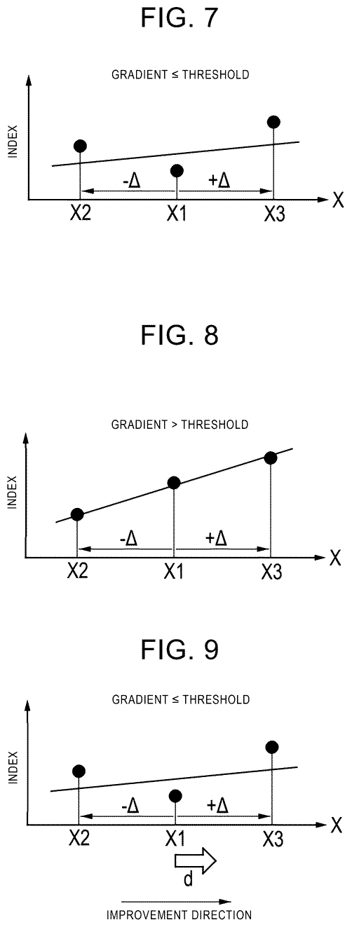

FIGS. 7 and 8 show examples of acquiring values of the index. In FIGS. 7 and 8, the adjustment target axis is the X axis. X1 indicates the current irradiation position. X2 indicates a search position changed by −Δ from the irradiation position X1 in the X-axis direction. X3 indicates a search position changed by +Δ from the irradiation position X1 in the X-axis direction. The solid line is an approximate straight line. FIG. 7 shows a case in which the gradient is equal to or less than the threshold. FIG. 8 shows a case in which the gradient is more than the threshold.

FIG. 9 shows an example of a process for changing the irradiation position in a case in which the gradient is equal to or less than the threshold. In the example shown in FIG. 9, since the direction from the irradiation position X1 toward the search position X3 is the improvement direction, the irradiation position X1 is changed by the minute amount d in the direction toward the search position X3.

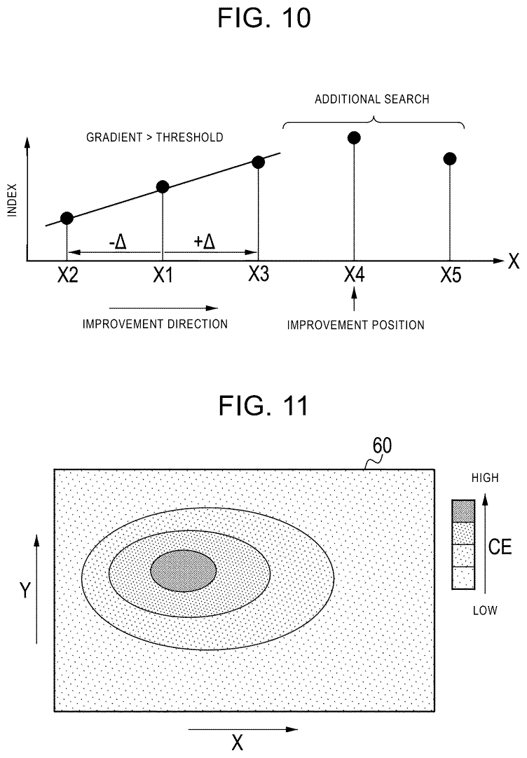

FIG. 10 shows an example of a process for additional search and changing the irradiation position in a case in which the gradient is more than the threshold. In the example shown in FIG. 10, since the direction from the irradiation position X1 toward the search position X3 is the improvement direction, additional search is performed in the direction opposite to the direction to the irradiation position X1 from the search position X3. In the example shown in FIG. 10, values of the index are acquired at the search position X4 changed from the search position X3 by +Δ and the search position X5 changed from the search position X4 by +Δ. Since the value of the index at the search position X5 is deteriorated from the value of the index at the search position X4, the search position X4 is the improvement position.

### 2.3 Problem

When the incident angle of the pulse laser light 31 on the light concentrating unit 60 is changed for the irradiation position adjustment, the incident position of the pulse laser light 31 on the light concentrating unit 60 varies. It has been confirmed that the light concentrating unit 60 has an optical characteristic that the spot intensity distribution of the pulse laser light 31 at the plasma generation region R1 changes depending on the incident position of the pulse laser light 31 due to the accuracy of the wavefront state. Therefore, there is a possibility that the value of the index for the irradiation position adjustment decreases due to the variation in the spot intensity distribution with the change in the incident position. Here, the change in the spot intensity distribution includes a change in the spot shape.

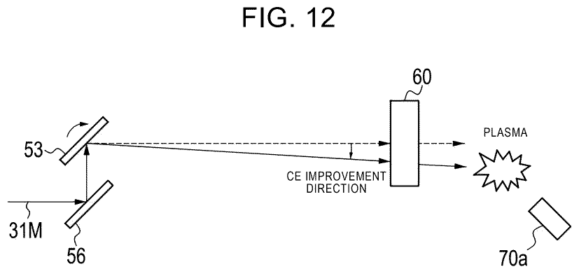

FIG. 11 conceptually shows the relationship between the incident position of the MPL light 31M on the light concentrating unit 60 and the CE. In FIG. 11, the incident position is shown as a position in the XY plane. For example, as shown in FIG. 12, the incident position of the MPL light 31M on the light concentrating unit 60 varies when the incident angle of the MPL light 31M on the light concentrating unit 60 is adjusted by adjusting the high reflection mirror 53 so as to improve the CE in the MPL irradiation position adjustment. When the incident position thus varies, the CE may greatly decrease depending on the incident position.

For example, there is a problem that the control margin of the EUV energy decreases when the CE decreases. Further, since the decrease in the CE corresponds to the irradiation condition of the pulse laser light 31 with respect to the target 27 deviating from a proper range, there is a fear that debris is generated due to the decrease in the CE and that the EUV light concentrating mirror 23 is contaminated. Further, the CE varies as the MPL irradiation position adjustment is repeatedly performed, and there is a fear that the EUV energy stability at the intermediate focal point IF is decreased.

As described above, in the EUV light generation system 11 according to the comparative example, the incident position of the pulse laser light 31 on the light concentrating unit 60 is varied and the spot intensity distribution is changed, so that the value of the index for the irradiation position adjustment may be decreased and characteristics related to EUV light generation may be deteriorated. Accordingly, it is desired to realize irradiation position control in which the variation in the spot intensity distribution can be suppressed.

### 3. First Embodiment

The EUV light generation system 11 according to a first embodiment will be described. Duplicate description of the same configuration and operation as those of the comparative example will be omitted unless specific description is needed.

### 3.1 Configuration

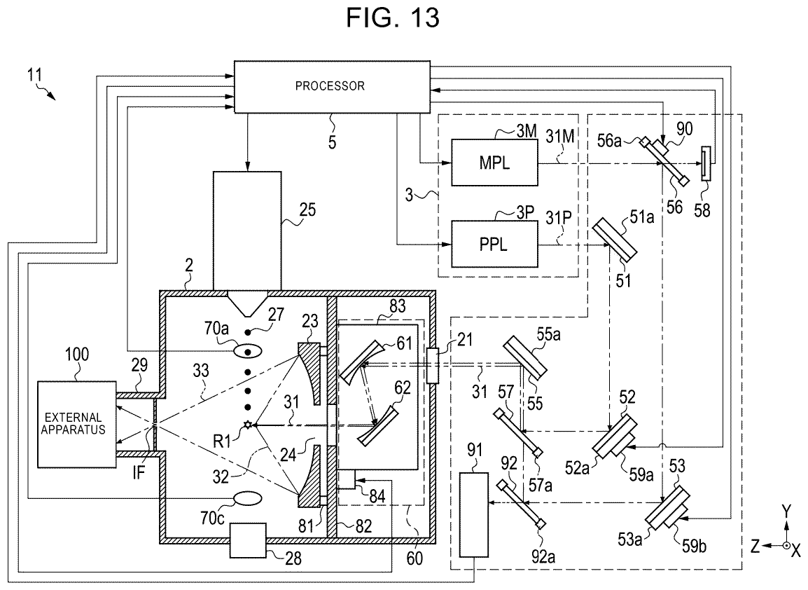

FIG. 13 shows the configuration of the EUV light generation system 11 according to the first embodiment. The configuration of the EUV light generation system 11 according to the present embodiment is different from that of the comparative example only in that an actuator 90 and a beam monitor 91 are further included and a beam splitter 92 is provided instead of the high reflection mirror 54.

The actuator 90 is attached to the holder 56a holding the beam splitter 56. The actuator 90 is connected to the processor 5 and adjusts the incident position of the MPL light 31M on the light concentrating unit 60 by changing the angle of the beam splitter 56.

The high reflection mirror 53 and the actuator 59b configure an “angle adjustment mirror” for adjusting the incident angle of the MPL light 31M on the light concentrating unit 60. Further, the beam splitter 56 and the actuator 90 configure a “position adjustment mirror” for adjusting the incident position of the MPL light 31M on the light concentrating unit 60. In the present embodiment, the position adjustment mirror is arranged upstream of the angle adjustment mirror on the optical path of the MPL light 31M.

The beam splitter 92 is arranged on the optical path of the MPL light 31M reflected by the high reflection mirror 53. The beam splitter 92 is configured to reflect the MPL light 31M at a high reflectance. Further, the beam splitter 92 is configured to transmit a part of the MPL light 31M toward the beam monitor 91.

In the present embodiment, the combiner 57 is arranged at a position where the optical path of the PPL light 31P reflected by the high reflection mirror 52 intersects with the MPL light 31M reflected by the beam splitter 92, and substantially matches the optical path axes of the PPL light 31P and the MPL light 31M.

Here, the MPL light 31M reflected by the beam splitter 92 may enter the beam monitor 91, and the MPL light 31M transmitted through the beam splitter 92 may enter the combiner 57.

The beam monitor 91 is configured to be capable of measuring the incident angle of the MPL light 31M on the light concentrating unit 60. The incident angle of the MPL light 31M on the light concentrating unit 60 is an example of the “parameter related to variation in the incident position” according to the technology of the present disclosure.

In the present embodiment, the processor 5 performs control of correcting the incident position of the MPL light 31M on the light concentrating unit 60 based on the measurement value of the above parameter when adjusting the incident angle of the MPL light 31M on the light concentrating unit 60 in the MPL irradiation position adjustment. Specifically, when adjusting the incident angle, the processor 5 calculates the variation amount of the incident position corresponding to the deviation of the incident angle based on the incident angle of the MPL light 31M measured by the beam monitor 91. The processor 5 corrects the incident position so as to cancel the variation in the incident position by controlling the actuator 90 based on the calculated variation amount.

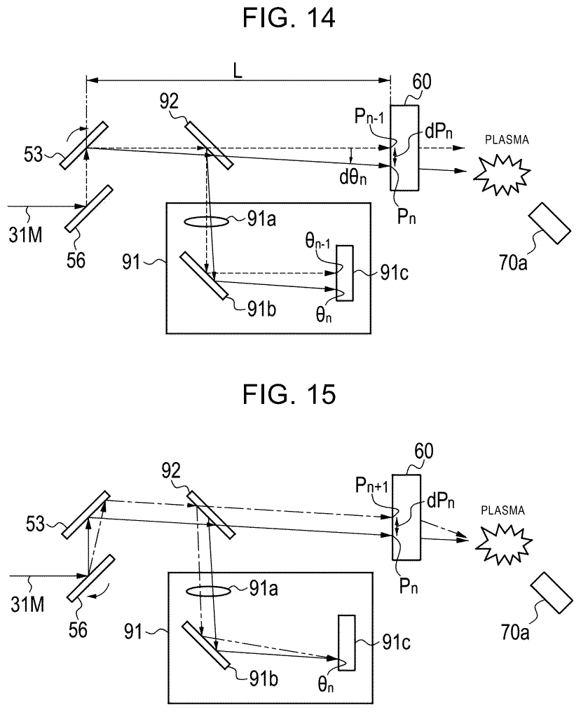

FIGS. 14 and 15 show the configuration of the beam monitor 91. In FIGS. 14 and 15, for the sake of simplicity of explanation, unlike FIG. 13, the MPL light 31M reflected by the beam splitter 92 is shown to enter the beam monitor 91. FIG. 14 shows operation of the MPL irradiation position adjustment. FIG. 15 shows correction operation of the incident position.

The beam monitor 91 includes a lens 91a, a high reflection mirror 91b, and an optical sensor 91c. The lens 91a is arranged on the optical path of the MPL light 31M entering the beam monitor 91. The high reflection mirror 91b is arranged on the optical path of the MPL light 31M transmitted through the lens 91a. The optical sensor 91c is arranged on the optical path of the MPL light 31M reflected by the high reflection mirror 91b. The lens 91a forms an image of the MPL light 31M entering the beam monitor 91 on the optical sensor 91c.

The optical sensor 91c measures the position of the MPL light 31M on a light receiving surface thereof. This position corresponds to the angle of the MPL light 31M incident on the beam splitter 92, that is, the incident angle of the MPL light 31M on the light concentrating unit 60. By using the optical sensor 91c as a two-dimensional optical sensor, the incident angle can be detected in each of the X-axis direction and the Y-axis direction. The optical sensor 91c is, for example, a two-dimensional beam profiler.

Here, the high reflection mirror 91b may not be provided in the beam monitor 91, and the optical sensor 91c may be arranged on the optical path of the MPL light 31M transmitted through the lens 91a.

### 3.2 Operation

The operation of the EUV light generation system 11 according to the present embodiment is similar to the operation of the EUV light generation system 11 according to the comparative example except for the operation of the MPL irradiation position adjustment.

In the present embodiment, when the MPL irradiation position adjustment is performed, the processor 5 calculates the angle deviation of the MPL light 31M with respect to the adjustment target axis direction based on the measurement value of the beam monitor 91. For example, as shown in FIG. 14, when the incident angle of the MPL light 31M is changed from θₙ₋₁ to θₙ, the processor 5 calculates an angle deviation dθₙ represented by Expression (1) described below.

dθₙ=θₙ−θₙ₋₁ (1)

The angle deviation dθₙ corresponds to an n-th command value that the processor 5 gives to the actuator 59b to adjust the high reflection mirror 53 in the MPL irradiation position adjustment.

Next, the processor 5 calculates a variation amount dPₙ of the incident position represented by Expression (2) described below based on the angle deviation dθₙ. Here, L is the optical path length from the high reflection mirror 53 to the light concentrating unit 60.

dPₙ=L×tan(dθₙ) (2)

When the angle deviation dθₙ is sufficiently small, the processor 5 may calculate the variation amount dPₙ based on Expression (3) described below.

dPₙ=L×dθₙ (3)

Then, as shown in FIG. 15, the processor 5 corrects the incident position by controlling the actuator 90 based on the variation amount dPₙ. Specifically, when the n-th incident position is Pn, the processor 5 controls the actuator 90 so that the (n+1)-th incident position Pₙ₊₁ satisfies Expression (4) described below.

Pₙ₊₁=Pₙ−dPₙ (4)

Accordingly, the incident position on the light concentrating unit 60 is maintained at the incident position prior to changing the incident angle of the MPL light 31M.

Here, although the control of correcting the incident position may be performed after changing the incident angle of the MPL light 31M, the control of correcting the incident position may be performed while changing the incident angle of the MPL light 31M. In this case, the processor 5 may correct the incident position based on the variation amount calculated based on the deviation of the incident angle while changing the incident angle of the MPL light 31M. Further, the processor 5 may correct the incident position every time the irradiation position is changed in the MPL irradiation position adjustment, but may correct the incident position only when the irradiation position is changed in the improvement direction described above.

When the light concentrating unit 60 is moved by the stage 84 in order to change the irradiation position, the movement amount of the light concentrating unit 60 may be added as an offset to the incident position Pₙ₊₁, which is a target value for correcting the incident position. Accordingly, it is possible to correct the incident position to which the movement amount of the light concentrating unit 60 is reflected.

### 3.3 Effect

In the present embodiment, when the incident angle of the MPL light 31M on the light concentrating unit 60 is adjusted to perform the MPL irradiation position adjustment, the incident position is corrected based on the angle deviation of the MPL light 31M. Accordingly, it is possible to change the incident angle while canceling the variation in the incident position of the MPL light 31M on the light concentrating unit 60. Therefore, according to the present embodiment, since the variation in the incident position of the MPL light 31M on the light concentrating unit 60 is canceled even when the MPL irradiation position adjustment is performed, the variation in the spot intensity distribution due to the variation in the incident position is suppressed. Accordingly, deterioration of the characteristics related to EUV light generation is suppressed.

Further, in the present embodiment, since the position adjustment mirror is arranged upstream of the angle adjustment mirror on the optical path of the MPL light 31M, it is possible to cancel the variation in the incident position while adjusting the incident angle with high accuracy. This is because the closer the angle adjustment mirror is to the light concentrating unit 60, the higher the adjustment accuracy of the incident angle is.

### 3.4 Modification

Next, various modifications of the first embodiment will be described.

### 3.4.1 First Modification

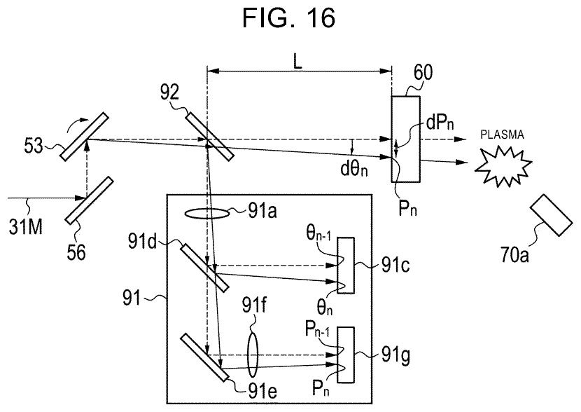

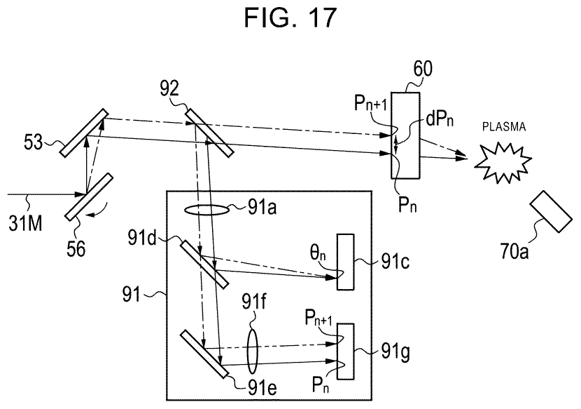

The EUV light generation system 11 according to a first modification is different from the first embodiment only in the configuration of the beam monitor 91. FIGS. 16 and 17 show the configuration of the beam monitor 91 according to the first modification. FIG. 16 shows operation of the MPL irradiation position adjustment. FIG. 17 shows correction operation of the incident position.

In the present modification, the beam monitor 91 is configured to be capable of measuring the incident angle and the incident position of the MPL light 31M on the light concentrating unit 60. Specifically, in addition to the configuration described above, the beam monitor 91 includes a beam splitter 91d provided instead of the high reflection mirror 91b, a high reflection mirror 91e, a lens 91f, and an optical sensor 91g.

The beam splitter 91d is arranged on the optical path of the MPL light 31M transmitted through the lens 91a, and reflects a part of the MPL light 31M incident thereon to enter the optical sensor 91c, and transmits another part of the MPL light 31M. The high reflection mirror 91e is arranged on the optical path of the MPL light 31M transmitted through the beam splitter 91d. The lens 91f is arranged on the optical path of the MPL light 31M reflected by the high reflection mirror 91e.

The optical sensor 91g is arranged on the optical path of the MPL light 31M transmitted through the lens 91f. The lens 91f configures a transfer optical system together with the lens 91a, and transfers an image of the MPL light 31M at the beam monitor 91 onto a light receiving surface of the optical sensor 91g.

The optical sensor 91g measures the position of the MPL light 31M on the light receiving surface. This position corresponds to the position of the MPL light 31M incident on the beam splitter 92, that is, the incident position of the MPL light 31M on the light concentrating unit 60. By using the optical sensor 91g being a two-dimensional optical sensor, the incident position can be detected in each of the X-axis direction and the Y-axis direction. The optical sensor 91g is, for example, a two-dimensional beam profiler.

Here, the beam monitor 91 may be configured so that the MPL light 31M transmitted through the beam splitter 91d enters the optical sensor 91c, and the MPL light 31M reflected by the beam splitter 91d is transmitted through the lens 91f and enters the optical sensor 91g.

In the present modification, the processor 5 calculates the angle deviation don from the target angle of the MPL irradiation position adjustment and the measurement value of the optical sensor 91c, and performs feedback control on the actuator 59b so that the incident angle becomes the target angle. At this time, feedback control is performed on the actuator 90 such that the measurement value of the optical sensor 91g approaches the incident position Pₙ₊₁ with the incident position Pₙ₊₁, being as the target position, calculated from the measurement value of the optical sensor 91c and Expression (4) described above. In the present modification, L in Expression (4) described above is the optical path length from the beam splitter 92 to the light concentrating unit 60. Thus, the incident position of the MPL light 31M on the light concentrating unit 60 is maintained at the target position. Then, the MPL irradiation position adjustment is performed by changing the target angle, and the incident position is automatically maintained.

Although the control of correcting the incident position may be performed after changing the incident angle of the MPL light 31M in the present modification as well, the control of correcting the incident position may be performed while changing the incident angle of the MPL light 31M. In this case, the processor 5 may correct the incident position based on the variation amount calculated based on the deviation of the incident angle while changing the incident angle of the MPL light 31M.

Further, the processor 5 may correct the incident position every time the target position is changed in the MPL irradiation position adjustment, but may correct the incident position only when the incident position is moved in the direction in which the performance in improved.

In the present modification, since the incident position is maintained while measuring the incident angle and the incident position of the MPL light 31M on the light concentrating unit 60, it is possible to change the incident angle more accurately while canceling the variation in the incident position of the MPL light 31M on the light concentrating unit 60.

### 3.4.2 Other Modification

In the embodiment and the modification described above, the incident position of the MPL light 31M on the light concentrating unit 60 is adjusted by changing the angle of the beam splitter 56. Alternatively, the incident position of the MPL light 31M on the light concentrating unit 60 may be adjusted by translating the beam splitter 56 along a plane including the incident optical axis and the reflection optical axis of the MPL light 31M on the beam splitter 56 without changing the angle of the beam splitter 56.

Further, in the embodiment and the modification described above, although the variation amount of the incident position is calculated based on the target value of the incident angle of the MPL light 31M on the light concentrating unit 60, the variation amount of the incident position may be calculated based on the measurement value of the incident position of the MPL light 31M on the light concentrating unit 60. That is, the incident position of the MPL light 31M on the light concentrating unit 60 is an example of the “parameter related to variation in the incident position” according to the technology of the present disclosure.

Further, in the embodiment and the modification described above, although the incident position is corrected based on the measurement value by the beam monitor 91, the incident position may be corrected based on the command value given to the actuator 59b for adjustment of the high reflection mirror 53 without using the beam monitor 91. This is because the adjustment amount of the high reflection mirror 53 corresponds to the deviation of the incident angle of the MPL light 31M on the light concentrating unit 60. That is, the adjustment amount of the high reflection mirror 53 is an example of the “parameter related to variation in the incident position” according to the technology of the present disclosure.

### 4. Second Embodiment

The EUV light generation system 11 according to a second embodiment will be described. Duplicate description of the same configuration and operation as those of the comparative example will be omitted unless specific description is needed.

### 4.1 Configuration

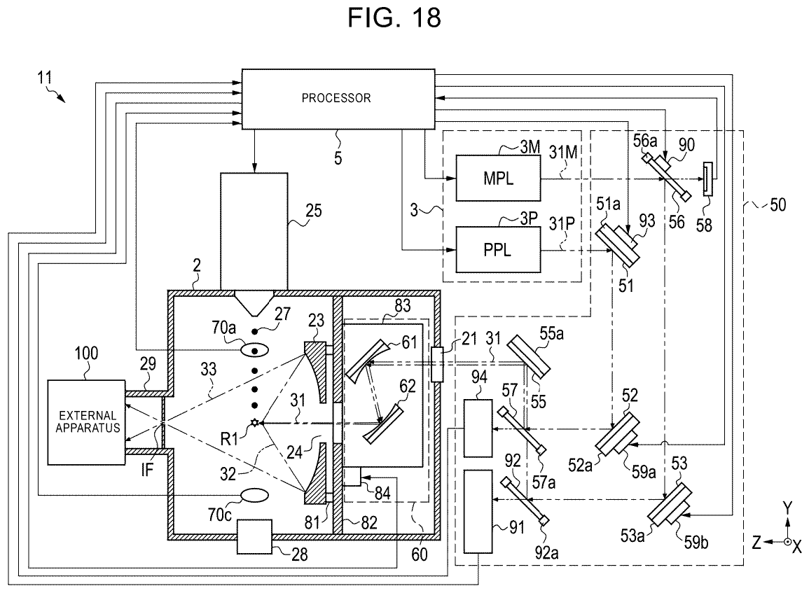

FIG. 18 shows the configuration of the EUV light generation system 11 according to the second embodiment. The configuration of the EUV light generation system 11 according to the present embodiment is different from that of the first embodiment only in that an actuator 93 and a beam monitor 94 are further included.

The actuator 93 is attached to the holder 51a holding the high reflection mirror 51. The actuator 93 is connected to the processor 5 and adjusts the incident position of the PPL light 31P on the light concentrating unit 60 by changing the angle of the high reflection mirror 51.

The beam monitor 94 is arranged on the optical path of the PPL light 31P transmitted through the combiner 57. The beam monitor 94 has a configuration similar to that of the beam monitor 91, and is configured to be capable of measuring the incident angle of the PPL light 31P on the light concentrating unit 60. The incident angle of the PPL light 31P on the light concentrating unit 60 is an example of the “first parameter related to variation in the incident position” according to the technology of the present disclosure. The beam monitor 94 corresponds to the “first beam monitor” according to the technology of the present disclosure.

In the present embodiment, the high reflection mirror 52 and the actuator 59a configure a “first angle adjustment mirror” for adjusting the incident angle of the PPL light 31P on the light concentrating unit 60. The high reflection mirror 51 and the actuator 93 configure a “first position adjustment mirror” for adjusting the incident position of the PPL light 31P on the light concentrating unit 60. In the present embodiment, the first position adjustment mirror is arranged upstream of the first angle adjustment mirror on the optical path of the PPL light 31P.

Further, the incident angle of the MPL light 31M on the light concentrating unit 60 is an example of the “second parameter related to variation in the incident position” according to the technology of the present disclosure. The beam monitor 91 corresponds to the “second beam monitor” according to the technology of the present disclosure.

The high reflection mirror 53 and the actuator 59b configure a “second angle adjustment mirror” for adjusting the incident angle of the MPL light 31M on the light concentrating unit 60. Further, the beam splitter 56 and the actuator 90 configure a “second position adjustment mirror” for adjusting the incident position of the MPL light 31M on the light concentrating unit 60. In the present embodiment, the second position adjustment mirror is arranged upstream of the second angle adjustment mirror on the optical path of the MPL light 31M.

In the present embodiment, the processor 5 performs control of correcting the incident position of the PPL light 31P on the light concentrating unit 60 based on the measurement value of the first parameter when adjusting the incident angle of the PPL light 31P on the light concentrating unit 60 in the PPL irradiation position adjustment. Specifically, when adjusting the incident angle of the PPL light 31P, the processor 5 calculates the variation amount of the incident position corresponding to the deviation of the incident angle based on the incident angle of the PPL light 31P measured by the beam monitor 94. The processor 5 corrects the incident position of the PPL light 31P so as to cancel the variation in the incident position by controlling the actuator 93 based on the calculated variation amount.

Further, similarly to the first embodiment, the processor 5 performs control of correcting the incident position of the MPL light 31M on the light concentrating unit 60 based on the measurement value of the second parameter when adjusting the incident angle of the MPL light 31M on the light concentrating unit 60 in the MPL irradiation position adjustment.

### 4.2 Operation

The operation of the EUV light generation system 11 according to the present embodiment is similar to the operation of EUV light generation system 11 according to the first embodiment except that the control of correcting the incident position is performed in the PPL irradiation position adjustment in addition to the MPL irradiation position adjustment. The control of correcting the incident position in the PPL irradiation position adjustment is similar to the control of correcting the incident position in the MPL irradiation position adjustment described in the first embodiment, and thus description thereof is omitted.

### 4.3 Effect

In the present embodiment, when the incident angle of the PPL light 31P on the light concentrating unit 60 is adjusted to perform the PPL irradiation position adjustment, the incident position is corrected based on the deviation of the angle of the PPL light 31P. Further, when the incident angle of the MPL light 31M on the light concentrating unit 60 is adjusted to perform the MPL irradiation position adjustment, the incident position is corrected based on the deviation of the angle of the MPL light 31M. Accordingly, it is possible to change the incident angle while canceling the variation in the incident positions of both of the PPL light 31P and the MPL light 31M. Therefore, according to the present embodiment, since the variation in the incident position on the light concentrating unit 60 is canceled even when the PPL irradiation position adjustment or the MPL irradiation position adjustment is performed, the variation in the spot intensity distribution due to the variation in the incident position is suppressed. Accordingly, deterioration of the characteristics related to EUV light generation is further suppressed.

Various modifications similar to those of the first embodiment can also be applied to the second embodiment.

### 5. Electronic Device Manufacturing Method

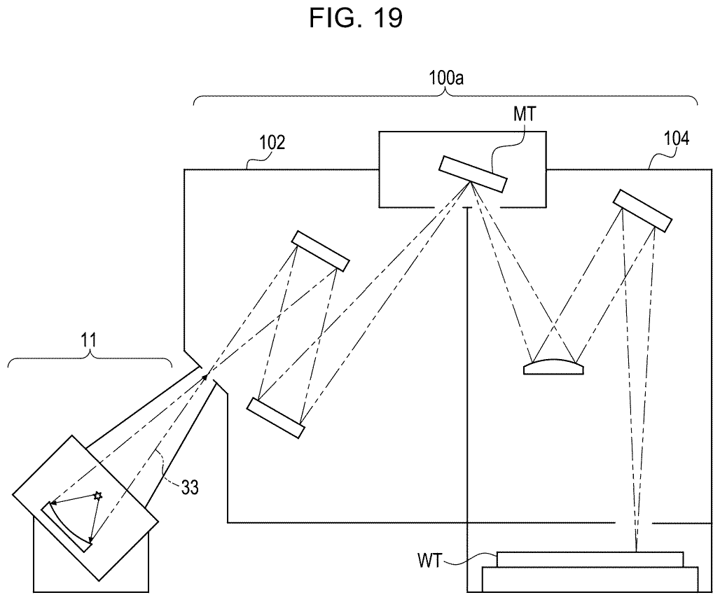

FIG. 19 schematically shows the configuration of the exposure apparatus 100a connected to the EUV light generation system 11. In FIG. 19, the exposure apparatus 100a as the external apparatus 100 includes a mask irradiation unit 102 and a workpiece irradiation unit 104. The mask irradiation unit 102 illuminates, via a reflection optical system, a mask pattern of a mask table MT with the EUV light 33 incident from the EUV light generation system 11. The workpiece irradiation unit 104 images the EUV light 33 reflected by the mask table MT onto a workpiece (not shown) arranged on a workpiece table WT via a reflection optical system. The workpiece is a photosensitive substrate such as a semiconductor wafer on which photoresist is applied. The exposure apparatus 100a synchronously translates the mask table MT and the workpiece table WT to expose the workpiece to the EUV light 33 reflecting the mask pattern. Through the exposure process as described above, a device pattern is transferred onto the semiconductor wafer, thereby an electronic device can be manufactured.

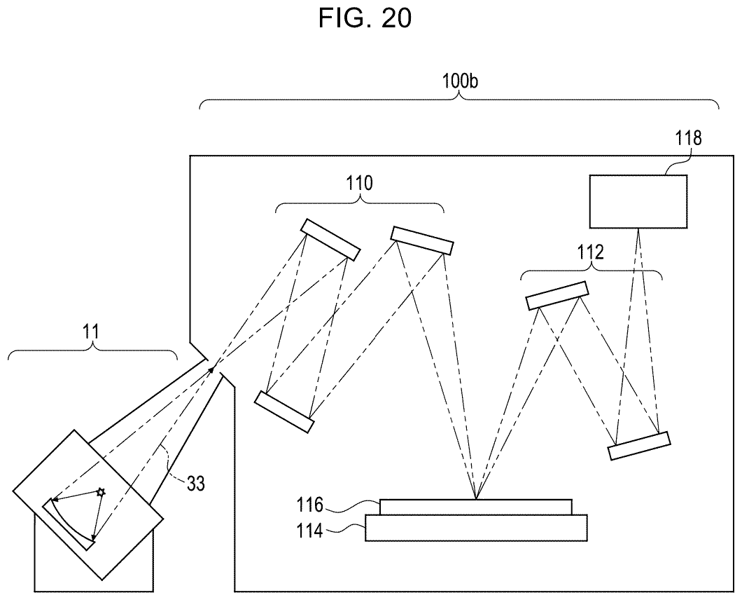

FIG. 20 schematically shows the configuration of an inspection apparatus 100b connected to the EUV light generation system 11. In FIG. 20, the inspection apparatus 100b as the external apparatus 100 includes an illumination optical system 110 and a detection optical system 112. The EUV light generation system 11 outputs, as a light source for inspection, the EUV light 33 to the inspection apparatus 100b. The illumination optical system 110 reflects the EUV light 33 incident from the EUV light generation system 11 to illuminate a mask 116 placed on a mask stage 114. Here, the mask 116 conceptually includes a mask blanks before a pattern is formed. The detection optical system 112 reflects the EUV light 33 from the illuminated mask 116 and forms an image on a light receiving surface of a detector 118. The detector 118 having received the EUV light 33 acquires an image of the mask 116. The detector 118 is, for example, a time delay integration (TDI) camera. Inspection for a defect of the mask 116 is performed based on the image of the mask 116 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 100a.

The processor 5 may be physically configured as hardware to execute various processes included in the present disclosure. For example, the processor 5 may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a central processing unit (CPU) or a special-purpose processing device such as a graphics processing unit (GPU).

Alternatively, the processor 5 may be programmed as software to execute the various processes included in the present disclosure. For example, the processor 5 may have a function of executing various processes implemented in a dedicated device such as an application specific integrated circuit (ASIC) or a programmable device such as a field programmable gate array (FPGA).

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements.

Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. An EUV light generation apparatus configured to generate EUV light by irradiating a target output into a chamber with laser light, comprising:
a light concentrating unit configured to concentrate the laser light on the target;
an angle adjustment mirror configured to adjust an incident angle of the laser light on the light concentrating unit;
a position adjustment mirror configured to adjust an incident position of the laser light on the light concentrating unit;
a beam monitor configured to measure a parameter related to variation in the incident position; and
a processor configured to perform control of adjustment by the position adjustment mirror based on a measurement value of the parameter when performing adjustment by the angle adjustment mirror.

2. The EUV light generation apparatus according to claim 1,
wherein the processor corrects the incident position so as to cancel the variation in the incident position by the control.

3. The EUV light generation apparatus according to claim 2,
wherein the processor calculates a variation amount of the incident position based on the measurement value, and corrects the incident position based on the variation amount.

4. The EUV light generation apparatus according to claim 3,
wherein the parameter is the incident angle, and the processor calculates the variation amount based on deviation of the incident angle.

5. The EUV light generation apparatus according to claim 1,
wherein the position adjustment mirror is arranged upstream of the angle adjustment mirror on an optical path of the laser light.

6. The EUV light generation apparatus according to claim 1,
wherein the processor changes an irradiation position of the laser light with respect to the target by changing the incident angle by adjusting by the angle adjustment mirror.

7. The EUV light generation apparatus according to claim 1,
wherein the laser light includes prepulse laser light radiated to the target and main pulse laser light radiated to the target to which the prepulse laser light has been radiated,
the angle adjustment mirror includes a first angle adjustment mirror for adjusting an incident angle of the prepulse laser light on the light concentrating mirror and a second angle adjustment mirror for adjusting an incident angle of the main pulse laser light on the light concentrating mirror,
the position adjustment mirror includes a first position adjustment mirror for adjusting an incident position of the prepulse laser light on the light concentrating mirror and a second position adjustment mirror for adjusting an incident position of the main pulse laser light on the light concentrating mirror,
the beam monitor includes a first beam monitor for measuring a first parameter related to variation in the incident position of the prepulse laser light on the light concentrating mirror and a second beam monitor for measuring a second parameter related to variation in the incident position of the main pulse laser light on the light concentrating mirror, and
the processor performs control of adjustment by the first position adjustment mirror based on a measurement value of the first parameter when performing adjustment by the first angle adjustment mirror and control of adjustment by the second position adjustment mirror based on a measurement value of the second parameter when performing adjustment by the second angle adjustment mirror.

8. The EUV light generation apparatus according to claim 7,
wherein the first position adjustment mirror is arranged upstream of the first angle adjustment mirror on an optical path of the prepulse laser light.

9. The EUV light generation apparatus according to claim 7,
wherein the second position adjustment mirror is arranged upstream of the second angle adjustment mirror on an optical path of the main pulse laser light.

10. An electronic device manufacturing method, comprising:
outputting EUV light generated by an EUV light generation apparatus to an exposure apparatus; and
exposing a photosensitive substrate to the EUV light in the exposure apparatus to manufacture an electronic device,
the EUV light generation apparatus being configured to generate the EUV light by irradiating a target output into a chamber with laser light, and including:
a light concentrating unit configured to concentrate the laser light on the target;
an angle adjustment mirror configured to adjust an incident angle of the laser light on the light concentrating unit;
a position adjustment mirror configured to adjust an incident position of the laser light on the light concentrating unit;
a beam monitor configured to measure a parameter related to variation in the incident position; and
a processor configured to perform control of adjustment by the position adjustment mirror based on a measurement value of the parameter when performing adjustment by the angle adjustment mirror.

11. An electronic device manufacturing method, comprising:
inspecting a defect of a mask by irradiating the mask with EUV light generated by an EUV light generation apparatus;
selecting a mask using a result of the inspection; and
exposing and transferring a pattern formed on the selected mask onto a photosensitive substrate,
the EUV light generation apparatus being configured to generate the EUV light by irradiating a target output into a chamber with laser light, and including:
a light concentrating unit configured to concentrate the laser light on the target;
an angle adjustment mirror configured to adjust an incident angle of the laser light on the light concentrating unit;
a position adjustment mirror configured to adjust an incident position of the laser light on the light concentrating unit;
a beam monitor configured to measure a parameter related to variation in the incident position; and
a processor configured to perform control of adjustment by the position adjustment mirror based on a measurement value of the parameter when performing adjustment by the angle adjustment mirror.
